(19) United States
(12) Patent Application Publication
(10) Pub. No.: US 2026/0231449 A1
(43) Pub. Date: Aug. 6, 2026

(54) SEMICONDUCTOR DEVICE AND METHOD FOR MANUFACTURING SEMICONDUCTOR DEVICE

(71) Applicant: Fujitsu Limited, Kawasaki-shi (JP)

(72) Inventor: Maciej Franciszek MATYS, Atsugi (JP)

(73) Assignee: Fujitsu Limited, Kawasaki-shi (JP)

(21) Appl. No.: 19/464,716

(22) Filed: Jan. 30, 2026

(30) Foreign Application Priority Data
Feb. 3, 2025 (JP) 2025-016029

(51) Int. Cl. H10D 8/60; H10D 8/01; H10D 62/10; H10D 62/824

(52) U.S. Cl. CPC H10D 8/60; H10D 8/051; H10D 62/124; H10D 62/824

(57) ABSTRACT

A semiconductor device includes a barrier layer, a channel layer, an anode electrode making a Schottky contact with the channel layer, and a cathode electrode making an ohmic contact with the channel layer. The channel layer is located between the barrier layer and the anode electrode. The channel layer includes an n-type first region, an n-type second region located between the first region and the anode electrode and in contact with the first region and the anode electrode, and a p-type third region located between the first region and the anode electrode and in contact with the first region, the second region, and the anode electrode.

### CROSS-REFERENCE TO RELATED APPLICATIONS

This application is based upon and claims the benefit of priority of Japanese Patent Application No. 2025-016029, filed on Feb. 3, 2025, the entire contents of which are incorporated herein by reference.

### FIELD

Certain aspects of the embodiments discussed herein are related to semiconductor devices, and methods for manufacturing the semiconductor devices.

### BACKGROUND

Conventionally, there is a known semiconductor device having a Schottky barrier diode that is provided with an anode electrode disposed on a first surface of a GaN substrate and a cathode electrode disposed on a second surface opposite from the first surface.

Related art include Japanese Laid-Open Patent Publication No. 2016-092083, Japanese National Publication of International Patent Application No. 2018-511933, U.S. Patent Application Publication No. 2019/0296157, and U.S. Patent Application Publication No. 2015/0041864, for example.

In the conventional semiconductor device, an on-state resistance of the semiconductor device is high.

### SUMMARY

It is an object in one aspect of the embodiments of the present disclosure to provide a semiconductor device and a method for manufacturing the semiconductor device capable of reducing an on-state resistance of the semiconductor device.

According to one aspect of the embodiments of the present disclosure, a semiconductor device includes a barrier layer; a channel layer; an anode electrode making a Schottky contact with the channel layer; and a cathode electrode making an ohmic contact with the channel layer, wherein the channel layer is located between the barrier layer and the anode electrode, and the channel layer includes an n-type first region; an n-type second region located between the first region and the anode electrode and in contact with the first region and the anode electrode; and a p-type third region located between the first region and the anode electrode and in contact with the first region, the second region, and the anode electrode.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating a semiconductor device according to a reference example;

FIG. 2 is a cross sectional view illustrating a semiconductor device according to a first embodiment;

FIG. 3 is a diagram illustrating characteristics of the semiconductor device according to the first embodiment;

FIG. 4 is a first cross sectional view illustrating a method for manufacturing the semiconductor device according to the first embodiment;

FIG. 5 is a second cross sectional view illustrating the method for manufacturing the semiconductor device according to the first embodiment;

FIG. 6 is a third cross sectional view illustrating the method for manufacturing the semiconductor device according to the first embodiment;

FIG. 7 is a fourth cross sectional view illustrating the method for manufacturing the semiconductor device according to the first embodiment;

FIG. 8 is a cross sectional view illustrating the semiconductor device according to a second embodiment;

FIG. 9 is a first cross sectional view illustrating the method for manufacturing the semiconductor device according to the second embodiment;

FIG. 10 is a second cross sectional view illustrating the method for manufacturing the semiconductor device according to the second embodiment; and

FIG. 11 is a third cross sectional view illustrating the method for manufacturing the semiconductor device according to the second embodiment.

### DESCRIPTION OF EMBODIMENTS

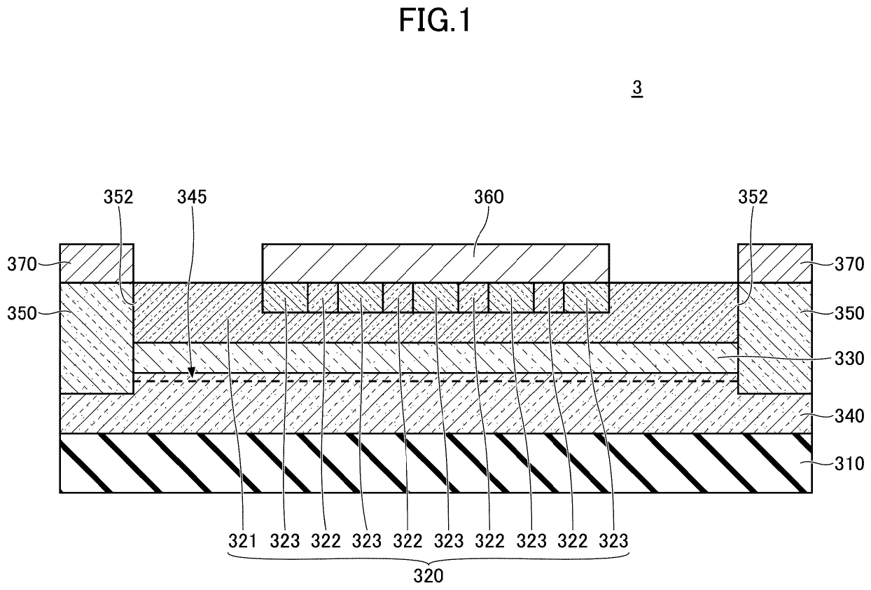

In order to reduce an on-state resistance of a Schottky barrier diode, that is, an electrical resistance of the Schottky barrier diode during an on state thereof, it is conceivable to employ a structure in which a channel layer is formed on a substrate, a barrier layer is formed on the channel layer, and a two-dimensional electron gas is generated near an upper surface of the channel layer. A reference example having such a structure will be described. The reference example is not a known, and is a semiconductor device studied by the present inventor in a process of conceiving embodiments which will be described later. FIG. 1 is a cross sectional view illustrating the semiconductor device according to the reference example.

As illustrated in FIG. 1, a semiconductor device 3 according to the reference example includes a substrate 310, a channel layer 340, a barrier layer 330, a junction barrier Schottky (JBS) layer 320, a regrowth layer 350, an anode electrode 360, and a cathode electrode 370.

The substrate 310 is an insulating substrate. The channel layer 340 is provided on the substrate 310. The channel layer 340 is a GaN layer. An upper surface of the channel layer 340 has a metallic polarity.

The barrier layer 330 is provided on the channel layer 340. The barrier layer 330 is an AlN layer. An upper surface of the barrier layer 330 has a metallic polarity. A band gap of the channel layer 340 is smaller than a band gap of the barrier layer 330. A channel 345 including a two-dimensional electron gas (2DEG) is located near the upper surface of the channel layer 340.

The JBS layer 320 is provided on the barrier layer 330. The JBS layer 320 is a GaN layer. An upper surface of the JBS layer 320 has a metallic polarity. The anode electrode 360 is provided on the JBS layer 320. The anode electrode 360 makes a Schottky contact with the JBS layer 320.

The JBS layer 320 includes an n-type first region 321, a plurality of n-type second regions 322, and a plurality of p-type third regions 323. The first region 321 is provided on the barrier layer 330. The first region 321 is in contact with the barrier layer 330. The second regions 322 are located between the first region 321 and the anode electrode 360, and are in contact with the first region 321 and the anode electrode 360. The third regions 323 are located between the first region 321 and the anode electrode 360, and are in contact with the first region 321, the second regions 322, and the anode electrode 360. That is, the second regions 322 and the third regions 323 are adjacent to one another in the plan view. The second regions 322 and the third regions 323 are alternately arranged. That is, the JBS layer 320 has a JBS structure. The anode electrode 360 is provided on the second regions 322 and the third regions 323.

A recess 352, penetrating the first region 321 of the JBS layer 320 and the barrier layer 330 and reaching a middle of the channel layer 340 in a thickness direction, is formed in the JBS layer 320, the barrier layer 330, and the channel layer 340. The regrowth layer 350 is provided inside the recess 352. An electrical resistance of the regrowth layer 350 is lower than an electrical resistance of the channel layer 340. The regrowth layer 350 is a GaN layer including an n-type impurity at a concentration higher than that of the channel layer 340.

The cathode electrode 370 is provided on the regrowth layer 350. The cathode electrode 370 makes an ohmic contact with the channel 345 of the channel layer 340 via the regrowth layer 350.

In the semiconductor device 3 according to the reference example, because a current flows between the anode electrode 360 and the cathode electrode 370 through the channel 345, an on-state resistance can be reduced compared to a conventional semiconductor device in which the anode electrode is provided on a first surface of a GaN substrate and a cathode electrode is provided on a second surface of the GaN substrate opposite from the first surface.

In the semiconductor device 3, when a reverse voltage exceeding a pinch-off voltage is applied between the anode electrode 360 and the cathode electrode 370, a depletion layer spreads between the second regions 322 and the third regions 323, and a current becomes less likely to flow between the anode electrode 360 and the channel 345. That is, an off-leakage current can be reduced.

However, in the configuration of the semiconductor device 3, it is difficult to reduce the pinch-off voltage. For example, it is difficult to make the pinch-off voltage 4 V or lower.

In view of the above, the present inventor conducted intensive studies for the purpose of lowering the pinch-off voltage while reducing the on-state resistance, and conceived the following embodiments.

Hereinafter, embodiments of the present disclosure will be specifically described with reference to the accompanying drawings. In the present specification and the drawings, constituent elements or components having substantially the same functional configuration are designated by the same reference numerals, and a redundant description may be omitted.

### First Embodiment

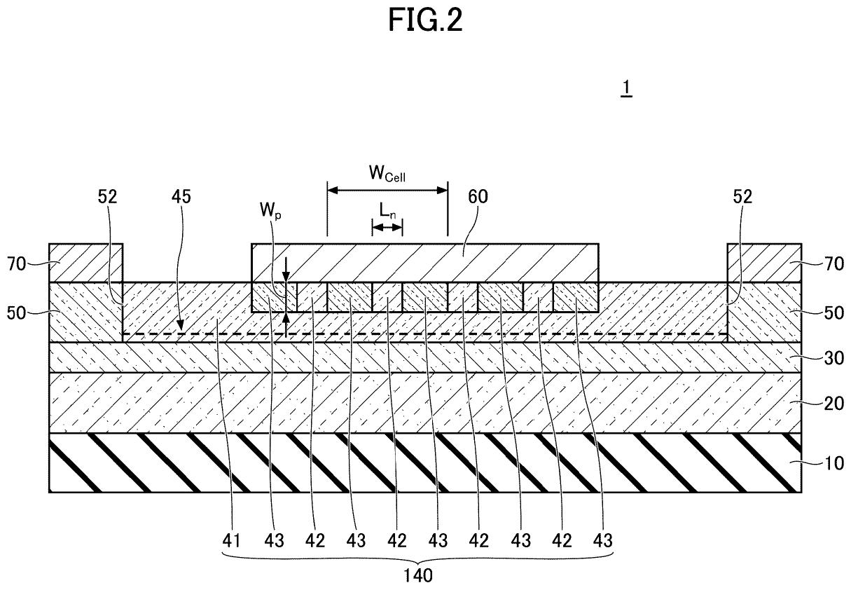

A first embodiment will be described. The first embodiment relates to a semiconductor device including a Schottky barrier diode (SBD). FIG. 2 is a cross sectional view illustrating the semiconductor device according to the first embodiment.

As illustrated in FIG. 2, a semiconductor device 1 according to the first embodiment includes a substrate 10, a buffer layer 20, a barrier layer 30, a channel layer 140, a regrowth layer 50, an anode electrode 60, and a cathode electrode 70.

The substrate 10 is an insulating substrate. The substrate 10 is a sapphire substrate, a SiC substrate, a GaN substrate, or a AlN substrate, for example.

The buffer layer 20 is provided on the substrate 10. The buffer layer 20 is a GaN layer, for example. A conductivity type of the buffer layer 20 is an n-type, for example. The conductivity type of the buffer layer 20 may be substantially intrinsic, that is, substantially an i-type without intentional addition of impurities to the buffer layer 20. An upper surface of the buffer layer 20 has nitrogen polarity.

The barrier layer 30 is provided on the buffer layer 20. The barrier layer 30 is a AlN layer, for example. The conductivity type of the barrier layer 30 is the n-type, for example. The conductivity type of the barrier layer 30 may be substantially the i-type without intentional addition of impurities to the barrier layer 30. An upper surface of the barrier layer 30, that is, the surface facing the channel layer 140 which will be described later has nitrogen polarity.

The channel layer 140 is provided on the barrier layer 30. A band gap of the channel layer 140 is smaller than a band gap of the barrier layer 30. The channel layer 140 is a GaN layer, for example. An upper surface of the channel layer 140 has a nitrogen polarity. A channel 45 including a two-dimensional electron gas (2DEG) is located near a lower surface of the channel layer 140. A thickness of the channel layer 140 is 500 nm or less, for example.

The anode electrode 60 is provided on the channel layer 140. That is, the channel layer 140 is located between the barrier layer 30 and the anode electrode 60. The anode electrode 60 makes a Schottky contact with the channel layer 140.

The channel layer 140 includes an n-type first region 41, an n-type second region 42, and a p-type third region 43. The first region 41 is provided on the barrier layer 30. For example, the first region 41 makes contact with the barrier layer 30. The second region 42 is located between the first region 41 and the anode electrode 60, and is in contact with the first region 41 and the anode electrode 60. The third region 43 is located between the first region 41 and the anode electrode 60, and is in contact with the first region 41, the second region 42, and the anode electrode 60. That is, the second region 42 and the third region 43 are adjacent to each other in the plan view. For example, the channel layer 140 includes a plurality of second regions 42 and a plurality of third regions 43, and the second regions 42 and the third regions 43 are alternately arranged. That is, the channel layer 140 has a JBS structure, for example. The anode electrode 60 is provided on the second regions 42 and the third regions 43. For example, the first region 41 and the second regions 42 include Si or Ge as an n-type impurity (donor), and the third regions 43 include Mg as a p-type impurity (acceptor). An impurity concentration of the first region 41 may be the same as an impurity concentration of the second region 42.

A recess 52 reaching the barrier layer 30 is formed in the first region 41 of the channel layer 140. The regrowth layer 50 is provided inside the recess 52. An electrical resistance of the regrowth layer 50 is lower than an electrical resistance of the first region 41 of the channel layer 140. The regrowth layer 50 is a GaN layer including an n-type impurity at a concentration higher than that of the first region 41.

The cathode electrode 70 is provided on the regrowth layer 50. The cathode electrode 70 makes an ohmic contact with the channel 45 of the channel layer 140 via the regrowth layer 50.

In the semiconductor device 1, because a current flows between the anode electrode 60 and the cathode electrode 70 through the channel 45, the on-state resistance can be reduced compared to that of the conventional semiconductor device, similar to the semiconductor device 3. Further, when a reverse voltage exceeding a pinch-off voltage is applied between the anode electrode 60 and the cathode electrode 70 of the semiconductor device 1, a depletion layer spreads between the second regions 42 and the third regions 43, and a current becomes less likely to flow between the anode electrode 60 and the channel 45. That is, an off-leakage current can be reduced.

Further, because the channel layer 140 is located between the barrier layer 30 and the anode electrode 60, a distance between the channel 45 and the anode electrode 60 in the semiconductor device 1 can be made smaller than a distance between the channel 345 and the anode electrode 360 of the semiconductor device 3. Accordingly, the pinch-off voltage of the semiconductor device 1 can be reduced to a voltage of 4 V or lower, for example.

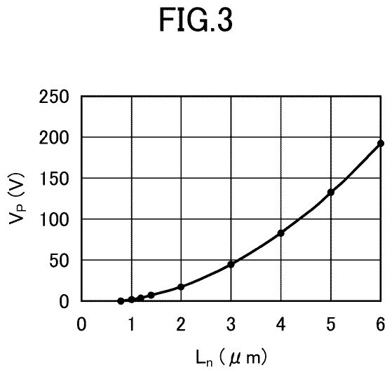

In the semiconductor device 1, a pinch-off voltage V_{P} depends on a distance (or length) Lₙ between the adjacent third regions 43, that is, a width of the second region 42, and the pinch-off voltage V_{P} decreases as the distance Lₙ decreases. FIG. 3 is a diagram illustrating characteristics of the semiconductor device according to the first embodiment. In FIG. 3, the abscissa indicates the distance Lₙ, and the ordinate indicates the pinch-off voltage V_{P}. The characteristics illustrated in FIG. 3 are calculated based on the following formula (1). In the formula (1), Na denotes a concentration of the donor in the second region 42, VB denotes a built-in voltage at a pn junction of the second region 42 and the third region 43, and as denotes a relative permittivity of the channel layer 140. In this example, Na is set to 2.5×10¹⁶ cm⁻³, VB is set to 3.4 V, and as is set to 10.4.

$${V}_{P} = \frac{{L}_{n}^{2} {qN}_{d}}{8 {ε}_{S}} - {V}_{B} \qquad ( 1 )$$

As illustrated in FIG. 3, in a range of the distance Lₙ greater than or equal to 1 μm and less than or equal to 4 μm, for example, the pinch-off voltage V_{P} varies greatly in a range of approximately 2 V or greater and approximately 100 V or less.

As the distance Lₙ decreases, the pinch-off voltage V_{P} decreases, but a channel resistance R_{Ch} in the thickness direction of the second region 42 increases. The channel resistance R_{Ch} can be expressed by the following formula (2). In the formula (2), Wp denotes a depth of the pn junction, W_{Cell} denotes a width of a unit cell constituted by one second region 42 and two third regions 43 sandwiching the second region 42 therebetween, and u denotes a mobility of carriers.

$${R}_{Ch} = \frac{{W}_{p} {W}_{Cell}}{μ {qN}_{d} {L}_{n}} \qquad ( 2 )$$

As illustrated in the formula (2), the channel resistance R_{Ch} is inversely proportional to the distance Lₙ and the impurity concentration N_{d}.

For example, in a case where the distance Lₙ is 0.5 μm and the concentration of carriers including the concentration of donors in the channel layer 140 and the concentration of carriers in the channel 45 is 8×10¹⁶ cm⁻³, the pinch-off voltage V_{P} is approximately 0.94 V. In this case, the channel resistance R_{Ch} is extremely small, that is, approximately 0.04 mΩ·cm². The distance Lₙ is preferably 0.2 μm or greater and 2.0 μm or less, and more preferably 0.4 μm or greater and 1.5 μm or less.

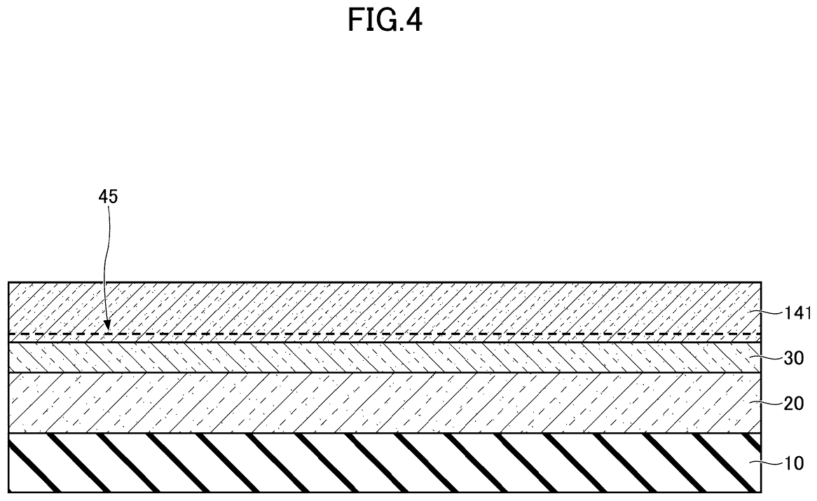

Next, a method for manufacturing the semiconductor device 1 according to the first embodiment will be described. FIG. 4 through FIG. 7 are cross sectional views illustrating the method for manufacturing the semiconductor device according to the first embodiment.

First, as illustrated in FIG. 4, the buffer layer 20 is formed on the substrate 10, the barrier layer 30 is formed on the buffer layer 20, and a channel layer 141 is formed on the barrier layer 30. The channel layer 141 is a layer that will later become the channel layer 140, and includes an n-type impurity at the same concentration as the first region 41 and the second regions 42. The buffer layer 20, the barrier layer 30, and the channel layer 141 may be formed by metal organic chemical vapor deposition (MOCVD), for example. The channel 45 including a 2DEG is generated near a lower surface of the channel layer 141.

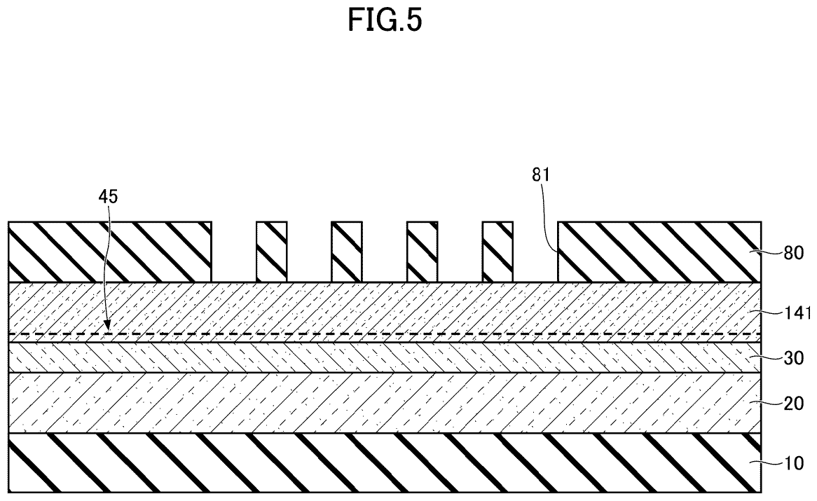

Next, as illustrated in FIG. 5, a mask 80 is formed on the channel layer 141. The mask 80 is formed of SiO₂, for example. The mask 80 has openings 81 through which regions where the third regions 43 are to be formed are exposed.

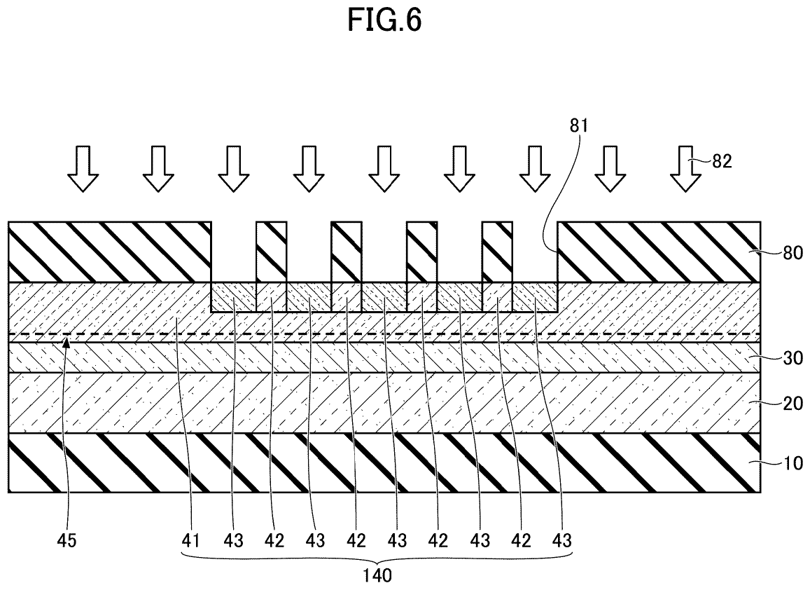

Thereafter, as illustrated in FIG. 6, ion implantation of a p-type impurity 82, such as Mg, for example, is performed into the channel layer 141 through the openings 81. As a result, the third regions 43 are formed in the channel layer 141. In addition, the channel layer 140 having the first region 41, the second regions 42, and the third regions 43 is obtained.

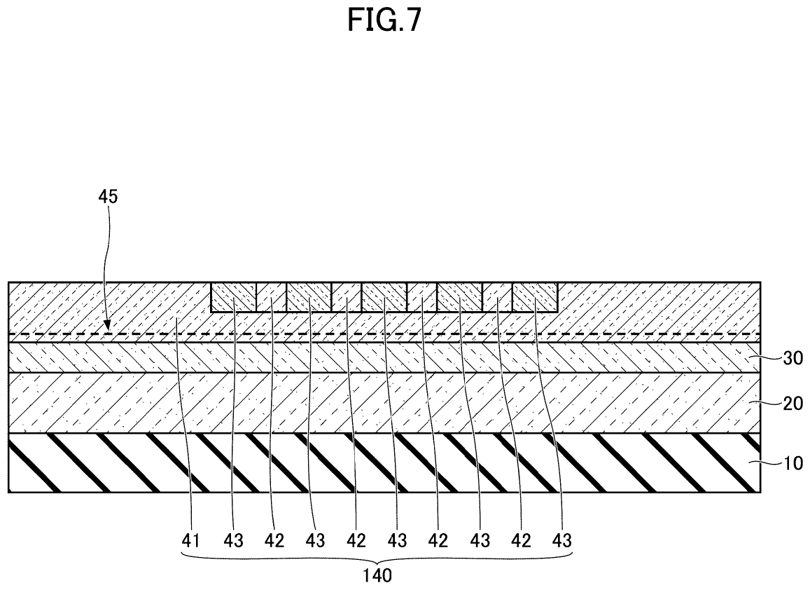

Subsequently, as illustrated in FIG. 7, the mask 80 is removed. Next, the p-type impurity is activated by annealing. The annealing, such as an ultra-high-pressure annealing (UHPA), a rapid thermal annealing (RTA), or the like can be performed.

Thereafter, the recess 52 is formed in the first region 41 of the channel layer 140, the regrowth layer 50 is formed inside the recess 52, the anode electrode 60 is formed on the second regions 42 and the third regions 43, and the cathode electrode 70 is formed on the regrowth layer 50, as illustrated in FIG. 2.

The semiconductor device 1 according to the first embodiment can be manufactured by the processes described above.

### Second Embodiment

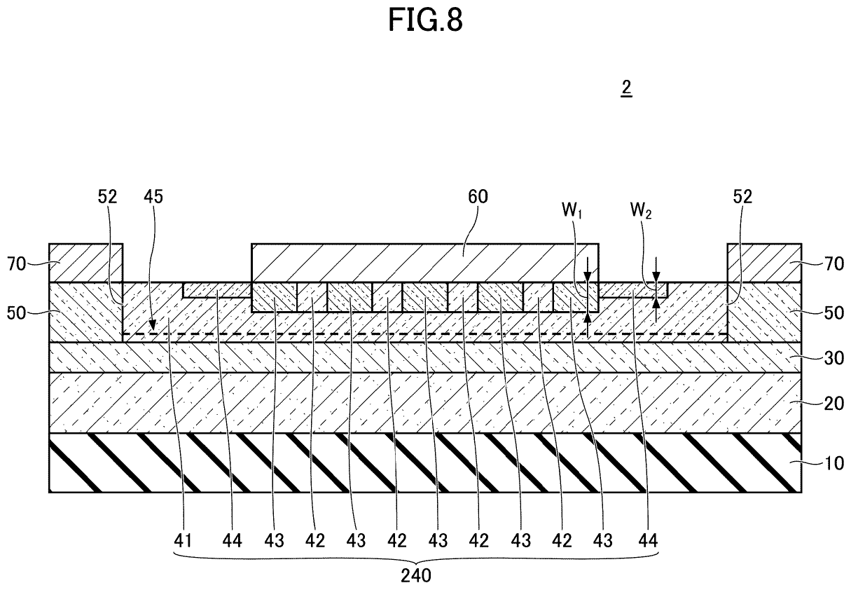

A second embodiment will be described. The second embodiment differs from the first embodiment in the configuration of the channel layer. FIG. 8 is a cross sectional view illustrating the semiconductor device according to the second embodiment.

As illustrated in FIG. 8, a semiconductor device 2 according to the second embodiment includes a channel layer 240 in place of the channel layer 140.

The channel layer 240 includes an n-type first region 41, n-type second regions 42, p-type third regions 43, and a p-type termination region 44. The termination region 44 is located between the anode electrode 60 and the cathode electrode 70 in the plan view, and is in contact with the third regions 43. The termination region 44 is spaced apart from the recess 52. For example, a thickness W₂ of the termination region 44 is smaller than a thickness W₁ of the third regions 43, and a p-type impurity concentration in the termination region 44 is lower than the p-type impurity concentration in the third regions 43. For example, the termination region 44 includes Mg as the p-type impurity.

Otherwise, the configuration of the second embodiment is the same as that of the first embodiment.

The semiconductor device 2 can also obtain the same effects as those obtainable by the first embodiment. In the semiconductor device 2, the channel layer 240 includes the termination region 44, and thus, it is possible to alleviate an electric field concentration near the third regions 43 in an off-state. In particular, the thickness W₂ of the termination region 44 is smaller than the thickness W₁ of the third regions 43, and thus a concentration of the 2DEG is higher below the termination region 44 than below the third regions 43. For this reason, a rate of change in the electric resistance in the channel 45 is small, and the electric field concentration can easily be alleviated. The thickness W₂ is preferably ⅔ the thickness W₁ or less, more preferably ½ the thickness W₁ or less, and still more preferably ⅓ the thickness W₁ or less.

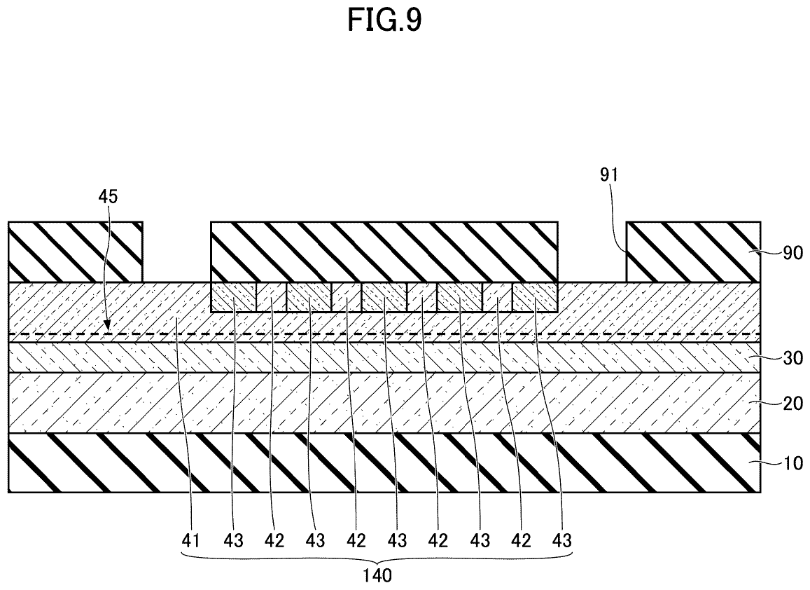

Next, the method for manufacturing the semiconductor device 2 according to the second embodiment will be described. FIG. 9 through FIG. 11 are cross sectional views illustrating the method for manufacturing the semiconductor device according to the second embodiment.

First, similar to the first embodiment, the processes up to the removal of the mask 80 are performed, as illustrated in FIG. 7. Next, as illustrated in FIG. 9, a mask 90 is formed on the channel layer 140. The mask 90 is formed of SiO₂, for example. The mask 90 has an opening 91 through which a region where the termination region 44 is to be formed is exposed.

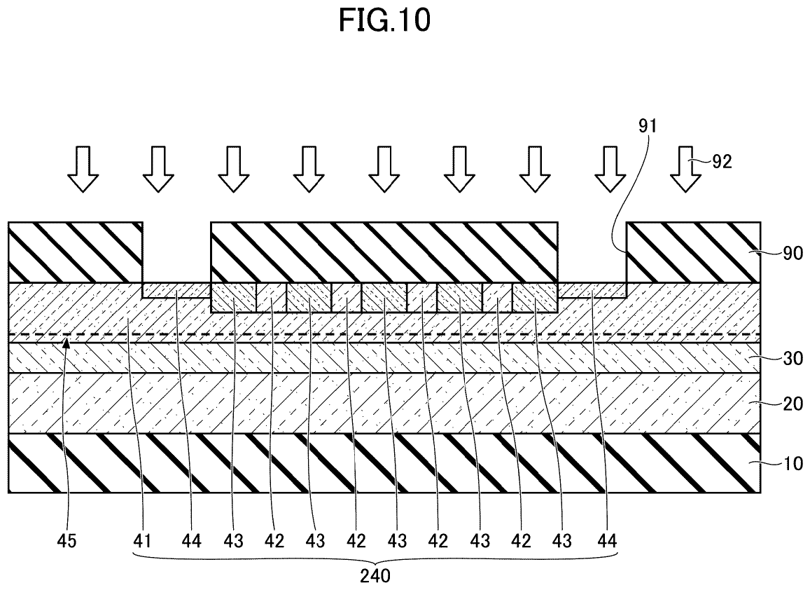

Thereafter, as illustrated in FIG. 10, ion implantation of a p-type impurity 92 is performed into the first region 41 through the opening 91. As a result, the termination region 44 is formed in the channel layer 140. In addition, the channel layer 240 having the first region 41, the second regions 42, the third regions 43, and the termination region 44 is obtained.

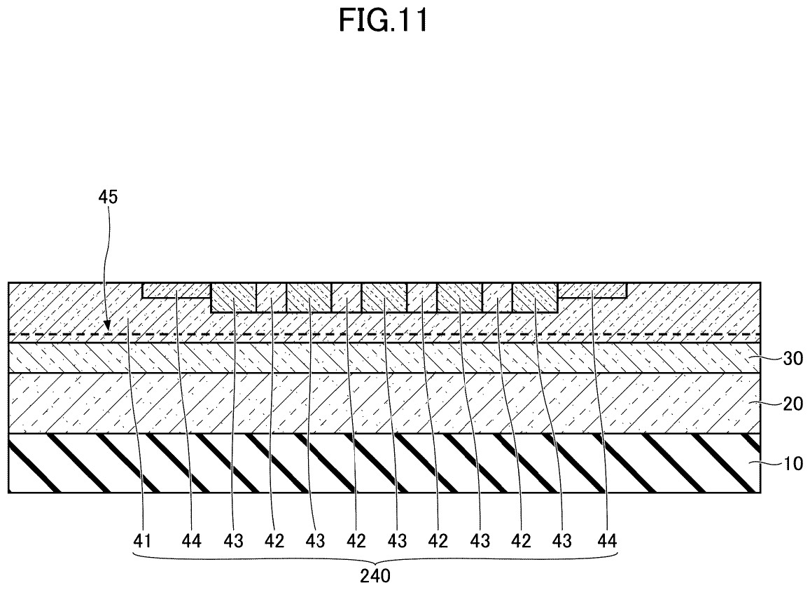

Subsequently, as illustrated in FIG. 11, the mask 90 is removed. Next, the p-type impurity is activated by annealing. The annealing, such as the UHPA, the RTA, or the like can be performed.

Thereafter, the recess 52 is formed in the first region 41 of the channel layer 240, the regrowth layer 50 is formed inside the recess 52, the anode electrode 60 is formed on the second regions 42 and the third regions 43, and the cathode electrode 70 is formed on the regrowth layer 50, as illustrated in FIG. 8.

The semiconductor device 2 according to the second embodiment can be manufactured by the processes described above.

In both the first embodiment and the second embodiment, the cathode electrode 70 may be formed inside the recess 52 without forming the regrowth layer 50. A composition of each compound semiconductor layer is not particularly limited, and a AlGaN layer may be used as the barrier layer 30, for example. That is, a AlₓGa₁₋ₓN layer may be used, where 0<x<=1.

Various aspects of the subject-matter described herein may be set out non-exhaustively in the following numbered clauses:

(Clause 1) A semiconductor device comprising:
a barrier layer;
a channel layer;
an anode electrode making a Schottky contact with the channel layer; and
a cathode electrode making an ohmic contact with the channel layer, wherein:
the channel layer is located between the barrier layer and the anode electrode, and
the channel layer includes:
   an n-type first region;
   an n-type second region located between the first region and the anode electrode and in contact with the first region and the anode electrode; and
   a p-type third region located between the first region and the anode electrode and in contact with the first region, the second region, and the anode electrode.

(Clause 2) The semiconductor device according to clause 1, wherein:
the channel layer includes a plurality of the second regions and a plurality of the third regions, and
the plurality of second regions and the plurality of third regions are alternately arranged in a plan view.

(Clause 3) The semiconductor device according to clause 1 or 2, wherein a surface of the barrier layer facing the channel layer has a nitrogen polarity.

(Clause 4) The semiconductor device according to any one of clauses 1 to 3, wherein:
the barrier layer is a AlₓGa₁₋ₓN layer, where 0<x<=1, and
the channel layer is a GaN layer.

(Clause 5) The semiconductor device according to any one of clauses 1 to 4, further comprising:
a substrate,
wherein the barrier layer is located between the substrate and the channel layer.

(Clause 6) The semiconductor device according to clause 5, wherein the substrate is a sapphire substrate, a SiC substrate, a GaN substrate, or an AlN substrate.

(Clause 7) The semiconductor device according to any one of clauses 1 to 6, wherein the third region includes Mg as an impurity.

(Clause 8) The semiconductor device according to any one of clauses 1 to 7, wherein the channel layer includes a p-type termination region located between the anode electrode and the cathode electrode in a plan view and in contact with the third region.

(Clause 9) The semiconductor device according to clause 8, wherein a thickness of the termination region is smaller than a thickness of the third region.

(Clause 10) The semiconductor device according to clause 8 or 9, wherein the termination region includes Mg as an impurity.

(Clause 11) A method for manufacturing a semiconductor device, comprising:
forming a barrier layer on a substrate;
forming an n-type channel layer on the barrier layer;
forming an anode electrode making a Schottky contact with the channel layer;
forming a cathode electrode making an ohmic contact with the channel layer;
between the forming the channel layer and the forming the anode electrode, performing ion implantation of a p-type impurity into the channel layer to form:
   an n-type first region;
   an n-type second region located between the first region and the anode electrode and in contact with the first region and the anode electrode; and
   a p-type third region located between the first region and the anode electrode and in contact with the first region, the second region, and the anode electrode; and
activating the p-type impurity.

(Clause 12) The method for manufacturing the semiconductor device according to clause 11, further comprising:
between the performing the ion implantation to form the first region, the second region, and the third region and the activating the p-type impurity, forming a p-type termination region in the channel layer by performing an ion implantation of a p-type impurity into the channel layer,
wherein the p-type termination region is located between the anode electrode and the cathode electrode in a plan view and is in contact with the third region.

According to the present disclosure, it is possible to reduce the on-state resistance of the semiconductor device.

Although the embodiments are numbered with, for example, “first,” or “second,” the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a barrier layer;
a channel layer;
an anode electrode making a Schottky contact with the channel layer; and
a cathode electrode making an ohmic contact with the channel layer, wherein:
the channel layer is located between the barrier layer and the anode electrode, and
the channel layer includes:
an n-type first region;
an n-type second region located between the first region and the anode electrode and in contact with the first region and the anode electrode; and
a p-type third region located between the first region and the anode electrode and in contact with the first region, the second region, and the anode electrode.

2. The semiconductor device as claimed in claim 1, wherein:
the channel layer includes a plurality of the second regions and a plurality of the third regions, and
the plurality of second regions and the plurality of third regions are alternately arranged in a plan view.

3. The semiconductor device as claimed in claim 1, wherein a surface of the barrier layer facing the channel layer has a nitrogen polarity.

4. The semiconductor device as claimed in claim 1, wherein:
the barrier layer is a AlₓGa₁₋ₓN layer, where 0<x<=1, and
the channel layer is a GaN layer.

5. The semiconductor device as claimed in claim 1, further comprising:
a substrate,
wherein the barrier layer is located between the substrate and the channel layer.

6. The semiconductor device as claimed in claim 5, wherein the substrate is a sapphire substrate, a SiC substrate, a GaN substrate, or an AlN substrate.

7. The semiconductor device as claimed in claim 1, wherein the third region includes Mg as an impurity.

8. The semiconductor device as claimed in claim 1, wherein the channel layer includes a p-type termination region located between the anode electrode and the cathode electrode in a plan view and in contact with the third region.

9. The semiconductor device as claimed in claim 8, wherein a thickness of the termination region is smaller than a thickness of the third region.

10. The semiconductor device as claimed in claim 8, wherein the termination region includes Mg as an impurity.

11. A method for manufacturing a semiconductor device, comprising:
forming a barrier layer on a substrate;
forming an n-type channel layer on the barrier layer;
forming an anode electrode making a Schottky contact with the channel layer;
forming a cathode electrode making an ohmic contact with the channel layer;
between the forming the channel layer and the forming the anode electrode, performing ion implantation of a p-type impurity into the channel layer to form:
an n-type first region;
an n-type second region located between the first region and the anode electrode and in contact with the first region and the anode electrode; and
a p-type third region located between the first region and the anode electrode and in contact with the first region, the second region, and the anode electrode; and
activating the p-type impurity.

12. The method for manufacturing the semiconductor device as claimed in claim 11, further comprising:
between the performing the ion implantation to form the first region, the second region, and the third region and the activating the p-type impurity, forming a p-type termination region in the channel layer by performing an ion implantation of a p-type impurity into the channel layer,
wherein the p-type termination region is located between the anode electrode and the cathode electrode in a plan view and is in contact with the third region.
